(19) United States
(12) Patent Application Publication
(10) Pub. No.: US 2009/0056796 A1
(43) Pub. Date: Mar. 5, 2009

(54) Structure Of An Edge Conducting Double-Sided Flip-Chip Solar Cell

(76) Inventor: Paul Pei, Tao-Yuan (TW)

Correspondence Address: Mr. Brian R. Coleman;Perkins Coie. LLP, 101 Jefferson Drive, Menlo Park, CA, 94025-1114, US

(21) Appl. No.: 11/847,040

(22) Filed: Aug. 29, 2007

(51) Int. Cl. H01L 31/072

(52) U.S. Cl. 136/255

(57) ABSTRACT

The present invention offers a structure of an edge conducting double-sided flip-chip solar cell with the p-n junction on both sides and on the edge of the chip to increase the conversion efficiency of the sun light. Both the n-type and the p-type bounding pads are in the back side only to avoid both wire bonding of the n-type contact and the p-type contact on the front side to increase the exposing area to the sun light. A metal layer is formed on the edge of the chip to conduct the current and heat corrected from the metal grids or fingers on the front side to the back side.

### BACKGROUND OF THE INVENTION

1. Field of the Invention

The present invention relates to double-sided solar cell. In particular, the present invention relates to a structure of edge conducting double sided flip-chip solar cell whereby both n-type and p-type bounding pads are in the back side to increase the illumination area and the ability of heat sink.

2. Description of the Related Art

Recently, solar energy has been attracting attention as a promising substitute for existing energy sources. Various solar cells for converting radiant energy of sunlight to electric energy, which is more readily usable than any other energy, by virtue of the photoelectric effect of semiconductors have been developed and successfully put to actual uses. Various types of solar cells are known in the art. For example, as classified according to their material, silicon solar cell is the most popular one for its low cost and mass production capability. Group III-V compound solar cells and Group II-VI compound solar cells are also important for their high efficiency. The packaging structure of the solar cell is also important to increase the light incident area and increasing the transfer efficiency.

FIG. 1 illustrates the basic configuration of the most popular solar cell. The construction of this solar cell and a process for the production of this cell will be described below with reference to FIG. 1. A substrate 10, for example, is a p-type silicon wafer. An n-type doping 12 on the front side and 14 on the back side are made by diffusion or implantation to form a p-n junction 16 on the front side and 18 on the back side. Aluminum alloy 20 is form on the back side to form the p-contact. Contact grid or fingers 22 of known design is made by evaporation and etching on the front side to form the n-contact. The aluminum alloy 20 may short circuit the back side p-n junction 18, so that the back side p-n junction is no used. Finally, the wafer is scribed to desired chips. In this process, there is no p-n junction in the edge. It is, of cause, a single sided solar cell.

The technology used in U.S. Pat. No. 4,153,476 to Shelpuk described a double-sided solar cell package. The configuration of the solar cell as shown in FIG. 2, A substrate 10, for example, is a p-type silicon wafer. An n-type doping 12 on the front side and 14 on the back side are made by diffusion or implantation to form a p-n junction 16 on the front side and 18 on the back side. These are similar to the prior art of FIG. 1. Then, the n-type material is patterned and etched to form an opening window or strip 24 on the front side and 25 on the back side, contact grid or fingers 22 on the front side and 23 on the back side for n-type contact and strip 26 on the front side and 28 on the back side for p-type contact are made by evaporation and etching. This double sided solar cell has p-n junctions on both the front side and the backside, therefore may increase the efficiency of the solar cell. However, wire bonding is needed on both sides, assembly is still inconvenient and the efficient can not be increased.

In view of the foregoing, it should readily be apparent that there currently exists a need for a high efficiency solar cell structure, easy to assembly and the heat sink capability is also improved.

### OBJECTS OF THE INVENTION

It is therefore an object of the invention to provide a structure of an edge conducting double-sided flip-chip solar cell with the p-n junction on both sides and on the edge of the chip to increase the conversion efficiency of the sun light.

It is another object of the invention to provide a structure of an edge conducting double-sided flip-chip solar cell by forming a metal layer on the edge of the chip to conduct the current and heat collected from the metal grids or fingers on the front side to the back side, then conduct to the bonding pads on the substrate to decrease the conducting resistance and make the heat sink more efficient.

It is yet another object of the invention to provide a structure of an edge conducting double-sided flip-chip solar cell by forming a metal layer on the edge of the chip to avoid both wire bonding of the n-type contact and the p-type contact on the front side to increase the exposing area to the sun light.

### DISCLOSURE OF THE INVENTION

A first aspect of the present invention teaches a structure of an edge conducting double-sided flip-chip solar cell with the p-n junction on both sides and on the edge of the chip, both the n-type and the p-type bounding pads are in the back side only, and a metal layer is formed on the edge of the chip to conduct the current and heat collected from the metal grids or fingers on the front side to the back side, including: A wafer, with a first type doping, being cut to a square with oblique angle, such that the wafer will has a maximum square area from the round shape wafer. The wafer may be a silicon wafer, a II-V compound wafer or a II-VI compound wafer. The first type impurity is P-type for silicon wafer and N-type for III-V and II-VI compound wafer; A second type impurity, forming on the surface of the wafer to form a second type layer and pn-junction both on the front side, the backside and the edge. The second type impurity is N-type for silicon wafer and P-type for III-V and II-VI compound wafer; A crossed shape contact window, forming on the back side of said wafer; A plurality of contact grid, forming on the front side and the back side to form a second type contact, the contact grid on the back side also use as the bonding pad; A crossed shape first type contact, forming on the crossed shape contact window to be the first type contact and the bonding pad; A layer of silver paste, forming on the edge surface of said wafer. If necessary, a layer of transparent conducting film may be deposited on the front side of the wafer to decrease the contact resistance of the contact grids or fingers on the front side. The solar cell is bonding on a printed circuit board by flip-chip bonding.

### BRIEF DESCRIPTION OF THE DRAWINGS

The foregoing and other advantages of the invention will be more fully understood with reference to the description of the best embodiment and the drawing wherein:

FIG. 1 illustrates the basic configuration of the most popular solar cell.

FIG. 2 illustrates the configuration of a traditional double-sided solar cell package.

FIG. 3 is a top view from the front side of an edge conducting double-sided flip-chip solar cell in according to one embodiment of the present invention.

FIG. 4 is a top view from the back side of an edge conducting double-sided flip-chip solar cell in according to one embodiment of the present invention.

FIG. 5 is a cross sectional view of the structure of an edge conducting double-sided flip-chip solar cell as view from the line A-A′ in FIG. 4.

FIG. 6 is a cross sectional view of an edge conducting double-sided flip-chip solar cell as view from the line A-A′ in FIG. 4 has been bonded on a printed circuit board.

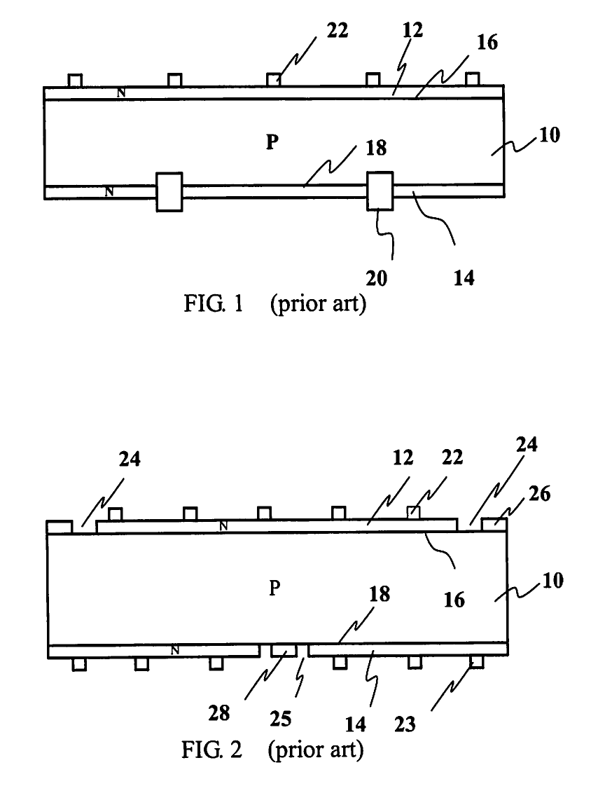

### DESCRIPTION OF THE PREFERRED EMBODIMENTS

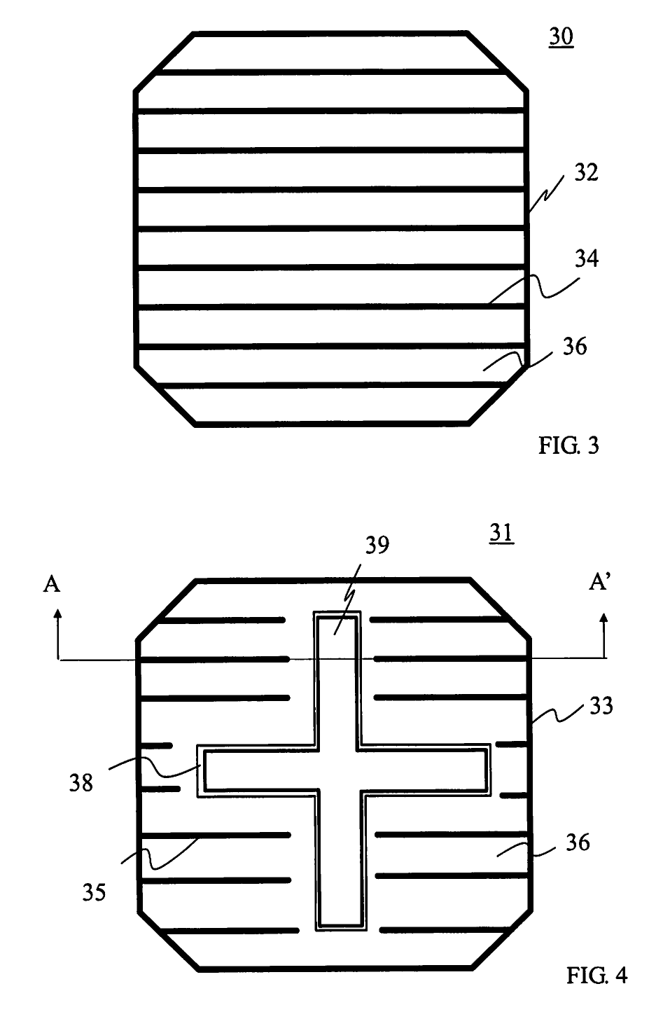

Refer to FIG. 3. FIG. 3 is a top view from the front side of an edge conducting double-sided flip-chip solar cell in according to one embodiment of the present invention. In this embodiment, the wafer is a P-type silicon wafer 30 (but if III-V compound wafer is used, the wafer is N-type) is cut to a square with oblique angle, such that the wafer will has a maximum square area from the round shape wafer. An N-type impurity (P-type for III-V compound) is then formed by implantation, diffusion or epitaxy on the surface to form an N-type layer 36 both on the front side, the backside and the edge thereof. Refer to FIG. 4. FIG. 4 is a top view from the back side of an edge conducting double sided solar cell in according to one embodiment of the present invention. A crossed shape of the N-type material 38 is etched away by protecting both the front side 30 and the back side 31 with photo-resist to expose the P-type (N-type for III-V or II-VI compound) to form a contact window. Then contact grids or fingers 34 on the front side and 35 on the back side for N-type contact and a crossed shape 39 for the P-type contact is form by evaporation or chemical vapor deposition (CVD) and lithography. If necessary, a layer of transparent conducting film may be deposited on the front side of the wafer to decrease the contact resistance of the contact grids or fingers 34 on the front side. Finally, a layer of silver paste 32 is formed on the edge surface of the edge conducting double sided flip-chip solar cell. In case of using CVD, since CVD is isotropic, the silver paste is not necessary.

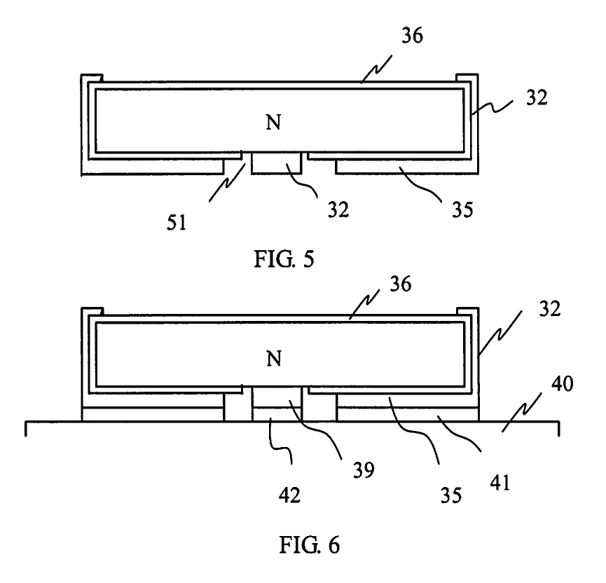

FIG. 5 is a cross sectional view of an edge conducting double-sided flip-chip solar cell as view from the line A-A′ in FIG. 4. Fingers 34 of the front side may or may not be seen. But the fingers on the front side are conduct by the silver paste on the edge to the contact grids or fingers 35 on the back side. The gap 51 isolates the N-type material on the back side from the crossed shape P-type contact 39.

FIG. 6 is a cross sectional view of an edge conducting double-sided flip-chip solar cell as view from the line A-A′ in FIG. 4 has been bonded on a printed circuit board. The printed circuit board 40 has printed grids or fingers 41 corresponding to the contact grids or fingers 35 on the back side, also crossed shape printed circuit 42. As the edge conducting double-sided flip-chip solar cell is flip-chip bonded to the printed circuit board 40, the contact grids or fingers 35 on the back side of the solar cell are bonded to the printed grids or fingers 41 and the crossed shape P-type contact 39 is bonded to the printed circuit 42. The N-type material 36 on the front side, the edge and the back side are almost exposed to the sun light, the current produced by the pn-junction on the front side of the solar cell will collect by the contact grids or fingers 34 on the front side and collected by the silver paste 32 to the contact grids or fingers 35 on the back side, then to the printed grids or fingers 41 on the printed circuit board 40. Thus, need not wire bonding from the front side to the printed circuit board 40 both the n-type contact grids or fingers and the p-type contact on the front side. This structure will increase the conversion efficiency of the sun light and decrease the conducting resistance and make the heat sink more efficient.

Although specific embodiments of the invention have been disclosed, it will be understood by those having skill in the art that minor changes can be made to the form and details of the specific embodiments disclosed herein, without departing from the scope of the invention. The embodiments presented above are for purposes of example only and are not to be taken to limit the scope of the appended claims.

What is claimed is:

1. A structure of an edge conducting double-sided flip-chip solar cell with the p-n junction on both sides and on the edge of the chip, both the n-type and the p-type bounding pads are in the back side only, and a metal layer is formed on the edge of the chip to conduct the current and heat collected from the metal grids or fingers on the front side to the back side, comprising:
a wafer, with a first type doping, being cut to a square with oblique angle, such that the wafer will has a maximum square area from the round shape wafer;
a second type impurity, forming on the surface of said wafer to form a second type layer and pn-junction both on the front side, the backside and the edge;
a crossed shape contact window, forming on the back side of said wafer;
a plurality of contact grid, forming on the front side and the back side to form a second type contact, said contact grid on the back side also use as the bonding pad;
a crossed shape first type contact, forming on said crossed shape contact window to be the first type contact and the bonding pad;
a layer of silver paste, forming on the edge surface of said wafer.

2. A structure as recited in claim 1, further comprising:
a layer of transparent conducting film is deposited on the front side of said wafer.

3. A structure as recited in claim 1, wherein said solar cell is bonding on a printed circuit board by flip-chip bonding.

4. A structure as recited in claim 1, wherein said wafer is silicon wafer.

5. A structure as recited in claim 1, wherein said wafer is III-V compound wafer.

6. A structure as recited in claim 1, wherein said wafer is II-VI compound wafer.

7. A structure as recited in claim 1, wherein said first type impurity is P-type for silicon wafer.

8. A structure as recited in claim 1, wherein said second type impurity is N-type for silicon wafer.

9. A structure as recited in claim 1, wherein said first type impurity is N-type for III-V and II-VI compound wafer.

10. A structure as recited in claim 1, wherein said second type impurity is P-type for III-VI compound wafer.
